(19) United States
(12) Patent Application Publication
(10) Pub. No.: US 2006/0145299 A1
(43) Pub. Date: Jul. 6, 2006

(54) Method for improving the electrical properties of active bipolar components

(75) Inventor: Christoph Bromberger, Heilbronn (DE)

Correspondence Address: MCGRATH, GEISSLER, OLDS & RICHARDSON, PLLC, P.O. BOX 1364, FAIRFAX, VA, 22038-1364, US

(73) Assignee: ATMEL GERMANY GMBH, Heilbronn (DE)

(21) Appl. No.: 11/352,312

(22) Filed: Feb. 13, 2006

(30) Foreign Application Priority Data
Aug. 13, 2003 (DE) 103 37 396.9
Jul. 6, 2004 (DE) 10 2004 032 548
Jul. 30, 2004 (DE) 10 2004 037 186
Aug. 12, 2004 (WO) PCT/EP04/09041

(51) Int. Cl. H01L 31/11

(52) U.S. Cl. 257/592

(57) ABSTRACT

A method for improving electrical characteristics of active bipolar components is provided. In conventional methods for improving the electrical characteristics of active bipolar components, the controllability of an input signal via an output signal is significantly affected, or the transient behaviour, in particular in the high-frequency range, is only slightly improved for a given blocking ability. According to the inventive method, triple-layer semiconductor assemblies are replaced by five-layer semiconductor assemblies and the tendency of the latter to imitate thyristor behaviour is suppressed with the aid of a heterotransition. The inventive method improves in particular the high-frequency characteristics and the blocking ability of active bipolar components, while the controllability of an input signal via an output signal is maintained to a great extent.

This nonprovisional application is a continuation of International Application PCT/EP2004/009041, which was filed on Aug. 12, 2004, and which claims priority to German Patent Application Nos. DE 10337396, DE 102004032548, and DE 102004037186, which were filed on Aug. 13, 2003, Jul. 6, 2004, and Jul. 30, 2004, respectively, and which are all herein incorporated by reference.

### BACKGROUND OF THE INVENTION

1. Field of the Invention

The present invention relates to a method for improving electrical properties of active bipolar components.

2. Description of the Background Art

Patent specification EP 0 493 854, which corresponds to U.S. Pat. No. 5,376,821, designated hereafter as D1, discloses vertically integrated cascode structures for high-voltage applications. Here, a geometrically underlying transistor with a high blocking capability is vertically integrated with a geometrically overlying transistor. Arrangements of this type are employed preferably within the voltage range above 100 V. The emitter region of the geometrically underlying transistor has, with the same conductivity type, a considerably higher dopant concentration than an adjacent collector drift zone of the geometrically overlying transistor. This increases the emitter effectiveness in particular of the geometrically underlying transistor. The vertical integration, for example, of two npn transistors produces a parasitic pnp transistor, so that the arrangement of D1 tends to have thyristor-like behavior and the collector current can be controlled only with limitations.

In patent specification EP 605920, designated hereafter as D2, the tendency of the arrangement from D1 to thyristor-like behavior is reduced by increasing the Gummel number G_{B} of the parasitic transistor. For this purpose, the emitter region of the lower transistor is made as a high-doped layer, which continuously separates the base of the lower transistor from the collector drift zone of the upper transistor by producing a MESA (Table Mountain) structure. In another embodiment, in D2 p-doped SiGe is used as an etching stop for the manufacture of the MESA structure in the base of the bottom transistor.

### SUMMARY OF THE INVENTION

It is therefore an object of the present invention to provide a method for improving the electrical properties of bipolar components. A further object of the invention is to disclose arrangements for bipolar components.

A feature of an embodiment of the invention is to change from a transistor to a vertically integrated cascode structure and to suppress the parasitic transistor by a heterotransition. For this purpose, in a transistor, having a first semiconductor region of a first conductivity type, a second semiconductor region, adjacent to the first semiconductor region, of a second conductivity type opposite to the first conductivity type, and a third semiconductor region, adjacent to the second semiconductor region, of the first conductivity type, the second semiconductor region being replaced by a sequence comprising a fourth semiconductor region of the second conductivity type made of a first semiconductor material in such a way that the fourth semiconductor region is adjacent to the first semiconductor region, a homogeneously doped fifth semiconductor region of the first conductivity type made of a second semiconductor material in such a way that the fifth semiconductor region is adjacent to the fourth semiconductor region, and a sixth semiconductor region of the second conductivity type in such a way that the sixth semiconductor region is adjacent to the fifth semiconductor region and the third semiconductor region, whereby the value of the energy gap in the first semiconductor material is lower by at least the average thermal energy of the charge carriers than the value of the energy gap in the second semiconductor material. Homogeneous doping of the fifth semiconductor region is understood to be that the dopant concentration in this semiconductor region deviates by less than two powers of ten, preferably by less than one power of ten.

By replacing the second semiconductor region by the fourth, fifth, and sixth semiconductor region, a novel vertically integratable cascode structure is produced, which is designated as a tetrode hereafter. In contrast to vertically integrated cascode structures, known from D1 or D2, between the fourth and fifth semiconductor region, the tetrode has no other semiconductor region with an increased dopant concentration in comparison with the fifth semiconductor region. The third semiconductor region is called the “emitter region” hereafter and the first semiconductor region the “collector region.” Furthermore, the fourth semiconductor region is called the “first base region,” the fifth semiconductor region the “intermediate base region,” and the sixth semiconductor region the “second base region.” In addition, a “parasitic transistor” is formed from the first base region, the intermediate base region, and the second base region.

The method can be used to produce components in which, in contrast to conventional components, electrical characteristics such as, for example, the transition frequency f_{T}, the power amplification, the Johnson product, and the product of the Early voltage Vₐ and current gain β are considerably improved without an increase in the chip area. In particular, both high-frequency tetrodes and power tetrodes can be manufactured using the new method by appropriately selecting the semiconductor materials and their doping profiles and layer thicknesses according to the field of application.

In a further embodiment of the method achieving the object, the third semiconductor region can be made in a third and the sixth semiconductor region from a fourth semiconductor material, whereby the value of the energy gap in the fourth semiconductor material is lower by at least the average thermal energy of the charge carriers than in the third semiconductor material. By this means, a partial transistor is made from the emitter region, the second base region, and the intermediate base region of the tetrode, produced by application of the method, as a hetero-bipolar transistor, and the transient behavior of the tetrode is improved; i.e., the cutoff frequency and/or the blocking capability are increased.

In another embodiment, a wider bandgap can be produced in the fourth semiconductor region at the edge to the fifth semiconductor region than at the edge to the first semiconductor region. In another further embodiment of the method, a wider bandgap is produced in the sixth semiconductor region at the edge to the third semiconductor region than at the edge to the fifth semiconductor region. In so doing, the change in the bandgap within the fourth and/or sixth semiconductor region can be made to be continuous, abrupt, or stepped. A quasi-electric field accelerating the minority charge carriers in an uncleared semiconductor region is produced by a suitable bandgap profile and the transition frequency f_{T} of the device produced by application of the further embodiment of the method is herewith advantageously increased.

In another further embodiment, the fourth semiconductor region can be made from a different semiconductor material than the first semiconductor region. By this means, particularly the breakdown voltage of the diode between the first and the fourth semiconductor region can be increased, without the transient properties of the components produced by the method being detrimentally affected. By a stepped or continuous configuration of the heterotransition between the first and the fourth semiconductor region, particularly piezoelectric effects and stresses in the crystal lattice can be reduced in lattice mismatches and an unimpeded flow of the charge carriers can also be assured in cases in which, due to an abrupt heterotransition, the movement of the charge carriers of the first conductivity type from the first base region into the collector region is impeded by a band edge step and the collector current is reduced and the saturation voltage increased.

In another further embodiment of the method, the sixth semiconductor region can be made from a different semiconductor material than the fifth semiconductor region. This makes it easier to carry out the method. Piezoelectric effects and stresses in the crystal lattice in lattice mismatches can be reduced by a stepped or continuous configuration of the heterotransition between the fifth and the sixth semiconductor region. Furthermore, an unimpeded flow of charge carriers can also be assured in cases in which due to an abrupt heterotransition the movement of charge carriers of the first conductivity type from the second base region to the intermediate base region is impeded by a band edge step.

In another further embodiment of the method, the fifth semiconductor region can be made with a higher dopant concentration than the first semiconductor region. Because the transient behavior can be improved by a high-doped intermediate base region, during the replacement of a transistor with a low dopant level in the collector, the intermediate base region can be more highly doped than the collector and a high Johnson product of high-blocking tetrodes is achieved in particular by this means.

In another further embodiment of the method, the fifth semiconductor region is made with a comparable dopant concentration as the first semiconductor region; i.e., the intermediate base region has a high dopant concentration comparable to the collector. An especially high Johnson product of high-frequency tetrodes can be achieved by this means.

In another further embodiment of the method, the fifth semiconductor region is made of n-doped Si and the fourth semiconductor region of p-doped SiGe. Because of the compatibility of silicon technology, this further embodiment can be implemented inter alia especially cost-effectively and simply. Moreover, a wiring-based combination with standard MOSFET transistors is made possible.

Novel multilayer components, particularly tetrodes, can be produced by the method with a first number of semiconductor layers of a first conductivity type and a second number of semiconductor layers of a second conductivity type, opposite to the first. In this context, the first number is greater than the number one, and the second number is greater by one than the first number. Each semiconductor layer of the first conductivity type is adjacent to two of the semiconductor layers of the second conductivity type.

A first semiconductor layer of the second number, adjacent to two semiconductor layers of the first number, consists of a first semiconductor material. A second semiconductor layer of the first number, adjacent to the first semiconductor layer, can be formed of a second semiconductor material. In this context, the first semiconductor layer is of the second conductivity type and the first semiconductor layer of first conductivity type.

According to the invention, the first semiconductor layer can have a homogeneous dopant distribution and the value of the energy gap in the second semiconductor material is lower by at least the average thermal energy of the charge carriers than the value of the energy gap in the first semiconductor material. Homogeneous doping of the first semiconductor region is understood to be that the dopant concentration in this layer deviates by less than two powers of ten, preferably by less than one power of ten.

Multilayer components in which the first number is greater than the number two, are also called “tetrodes” hereafter. Multilayer components with changed electrical characteristics, particularly with an increased Early voltage Vₐ and an increased power amplification, are achieved by a transition from a first tetrode with a first number of two to a second tetrode with a first number greater than two.

A first of the two semiconductor layers adjacent to precisely one semiconductor layer of the first conductivity type in a tetrode is called an “emitter region” hereafter, and the other of the two semiconductor layers adjacent to precisely one semiconductor layer of the first conductivity type, the “collector region” of the tetrode. The semiconductor layers of the second conductivity type of a tetrode are called “base regions” hereafter and the semiconductor layers of the first conductivity type, which are placed between two base regions, “intermediate base regions.”

For the operation of a tetrode, in general at least the collector region, the base regions, and the emitter region are electrically contacted. In another embodiment of the invention, individual or all intermediate base regions have electrical contacts. This enables suppression of a possible oscillation tendency.

The potential, which becomes established in an uncontacted intermediate base region, depends, on the one hand, on the collector current, but on the other, also participates in determining the collector current. Because of the ultimate transit and charging times, the potential in the intermediate base region reacts delayed in time to changes in the collector current, in the same way as the collector current adjusts initially with a delay to a potential change in the intermediate base region. This produces a control loop with a time constant. Individual embodiments tend to oscillate below the time constant. This oscillation tendency can be suppressed by defining the voltage in the intermediate base region by an electrical contact.

In another embodiment, all contacted semiconductor layers have an electrical contact connectable to the front of a semiconductor body. Regarded as the front, for example, is the side of a wafer that has the contact areas for component connections. Low connecting resistances are achieved by front contacting in the tetrodes with relatively thin semiconductor regions, so that, for example, a transient behavior important for the high-frequency region improves.

In another embodiment, contacting in the lowest semiconductor layer occurs from the back of the semiconductor body. As a result, the substrate material can be utilized as a collector drift zone to achieve a high dielectric strength of the tetrodes. Furthermore, components with a high ampacity can be connected with saving of space, thus being advantageous, in particular, in regions with a high voltage and high currents.

The tetrodes can be employed particularly as a high-blocking active component. Within a voltage range in which the transient behavior of a transistor is determined by the transit time through the base-collector space-charge region, an approximately 1.5-fold to 3-fold Johnson product of a high-blocking transistor can be achieved, for example, by means of a two-stage tetrode. Whereas the blocking capability of a two-stage tetrode is 3 to 10 times that of a transistor with comparable collector doping, the transition frequency f_{T} is inversely proportional to the root of the base-collector voltage, so that replacement of a high-blocking transistor with a two-stage tetrode increases the Johnson product by a factor of √3 to √10.

Typical fields of application for high-blocking tetrodes include, for example, active elements in switching power supplies and the control of piezoelectric actuators in printheads, microdosing pumps, loudspeakers, etc. In switching power supplies, the switching losses in particular can be considerably reduced with the use of tetrodes.

In an integrated circuit, the collector layer thickness can be reduced in the control of piezoelectric actuators within the voltage range of, for example, 200 V by replacing the previously employed semiconductor components with tetrodes. By this means, the packing density within the integrated circuit can be increased and a considerable cost reduction achieved.

A tetrode furthermore can be employed advantageously as a high-frequency-capable active component. Within a frequency range in which the transient behavior of a transistor is appreciably influenced by the Miller effect, a 3-fold to 10-fold Johnson product, in comparison with a transistor, can be achieved by a two-stage tetrode because of the higher achievable voltage swing ΔU_{c} and the avoidance of the Miller effect. Typical applications of high-frequency-capable tetrodes are, for example, mobile communication, as well as signal processing and the control of optical modulators for data transmission in fiber optic networks.

Furthermore, with use of tetrodes instead of transistors, a higher power amplification per amplifier stage can be achieved and the number of amplifier stages and the quiescent current uptake can be reduced. In mobile applications such as cell phones and notebooks, the charging interval for the energy carrier, particularly of accumulators, can be increased considerably as a result.

Whereas cost-effective, fully developed, and simple manufacturing processes for integrated circuits are available in the lower high-frequency range in the range of a few GHz or below one GHz, for applications in frequency ranges above the X-band a transition to other, less cost-effective semiconductor material systems, for example, GaAs, which are more costly to process, is frequently necessary. The frequency range accessible with a given semiconductor material system, particularly with silicon, is broadened with the use of tetrodes. The manufacturing costs for devices for signal processing within high frequency ranges are thus considerably reduced.

During data transmission in optical fiber networks, high modulation rates are possible by carrier frequencies of typically approximately 200 THz. Above a data rate of about 10 Gb/s, hereby a signal is modulated onto the beam of a continuously operated laser diode by a downstream optical modulator. Mach-Zehnder interferometers in particular, which require control voltages of up to about 10 V, are used as optical modulators. Unlike the situation with prior-art semiconductor components, high-frequency control signals within the required voltage range can be made available by tetrodes in a simple cost-effective manner.

Another possible circuit, which is also the subject of the invention, is a high-frequency cascode circuit. High frequency is preferably understood to be that a transient behavior within this high-frequency range is essentially influenced by the Miller effect. This high-frequency cascode circuit can have a first transistor, which is operated in the base circuit, and a second transistor, which is operated in the emitter circuit. In this context, the emitter of the second transistor and the collector of the first transistor form a continuous intermediate base region, which therefore is not separated by metallizations. The base-intermediate base transition of the first transistor is a heterotransition between two semiconductor materials with different bandgaps, which makes it possible to reduce the effect of the parasitic transistor. The intermediate base region is doped homogeneously hereby. Homogeneous doping of the intermediate base region is understood to be that the dopant concentration in this region deviates by less than two powers of ten, preferably by less than one power of ten.

In an advantageous further embodiment of this high-frequency cascode circuit of the invention, the dopant concentration is specified by the intermediate base region having a dopant concentration of at least 1·10¹⁷ cm⁻³, preferably greater than 5·10¹⁷ cm⁻³. By homogeneous doping, the intermediate base region, forming the collector of the first transistor, can be adapted to certain high-frequency properties of this transistor.

The high-frequency characteristic of the high-frequency-cascode circuit of the invention can be improved further by a preferred further embodiment of the invention in which the intermediate base region has a thickness of less than 200 nm, preferably of less than 100 nm. The high-frequency properties can be improved with a declining thickness. This is possible particularly because a high-doped region is not required in addition to the homogeneously doped intermediate base of the invention.

Another aspect of the invention, moreover, is a method for manufacturing a multilayer component, which has the following manufacturing steps. A first number of semiconductor layers of a first conductivity type and a second number of semiconductor layers of a second conductivity type are produced. In fact, several semiconductor layers of a conductivity type can essentially be produced simultaneously, for example, with a single implantation, but preferably, semiconductor layers of the first and of the second conductivity type are produced alternately to one another, for example, applied epitaxially.

According to the invention, the first number is greater than the number one and the second number is greater by one than the first number. Each semiconductor layer of the first conductivity type is produced in such a way that it is adjacent to two of the semiconductor layers of the second conductivity type. In so doing, a first semiconductor layer of the second conductivity type is produced from a first semiconductor material, the layer which is adjacent to two semiconductor layers of the first conductivity type. Moreover, a second semiconductor layer, adjacent to the first semiconductor layer, is produced from a second semiconductor material, whose value for the energy gap is lower by at least the average thermal energy of the charge carriers than the value of the energy gap in the first semiconductor material. A dopant is homogeneously distributed in the first semiconductor layer.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 illustrates a basic method with use of individual layer sequences;

FIG. 2a illustrates a course of the material composition in parts of two tetrodes;

FIG. 2b illustrates band diagrams following from FIG. 2a in the active forward operation;

FIG. 3a is a schematized cross section through a vertically integrated cascode structure;

FIG. 3b is the equivalent circuit of the vertically integrated cascode structure of FIG. 3a;

FIG. 3c is a schematized cross section through a two-stage tetrode;

FIG. 3d is an equivalent circuit of the tetrode of FIG. 3c;

FIG. 4a is a schematized cross section through a high-frequency tetrode; and

FIG. 4b a schematized cross section through a power tetrode.

### DETAILED DESCRIPTION

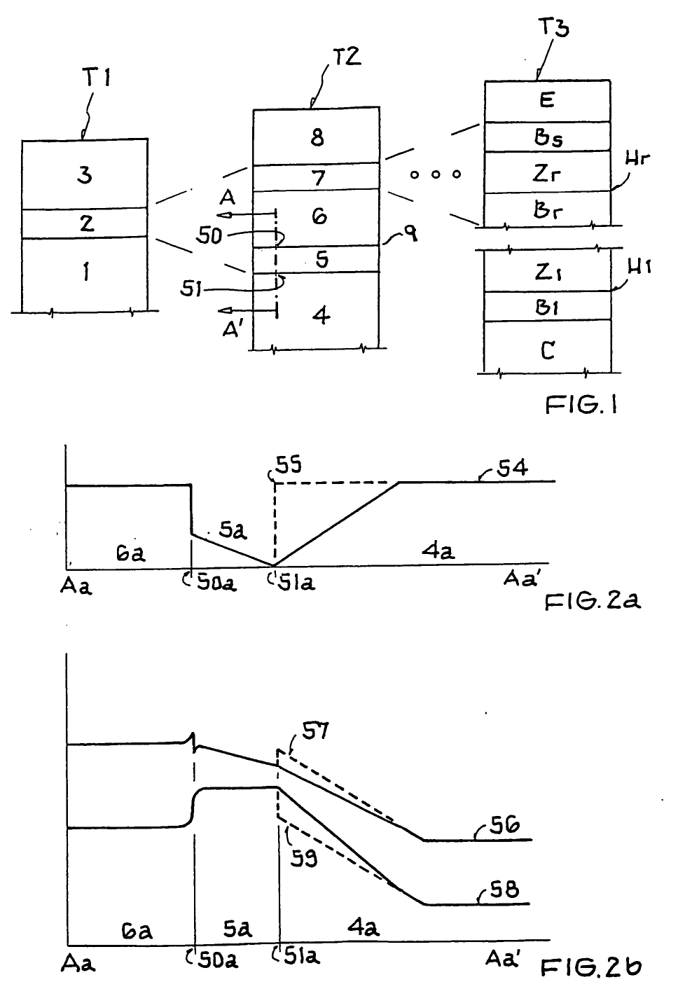

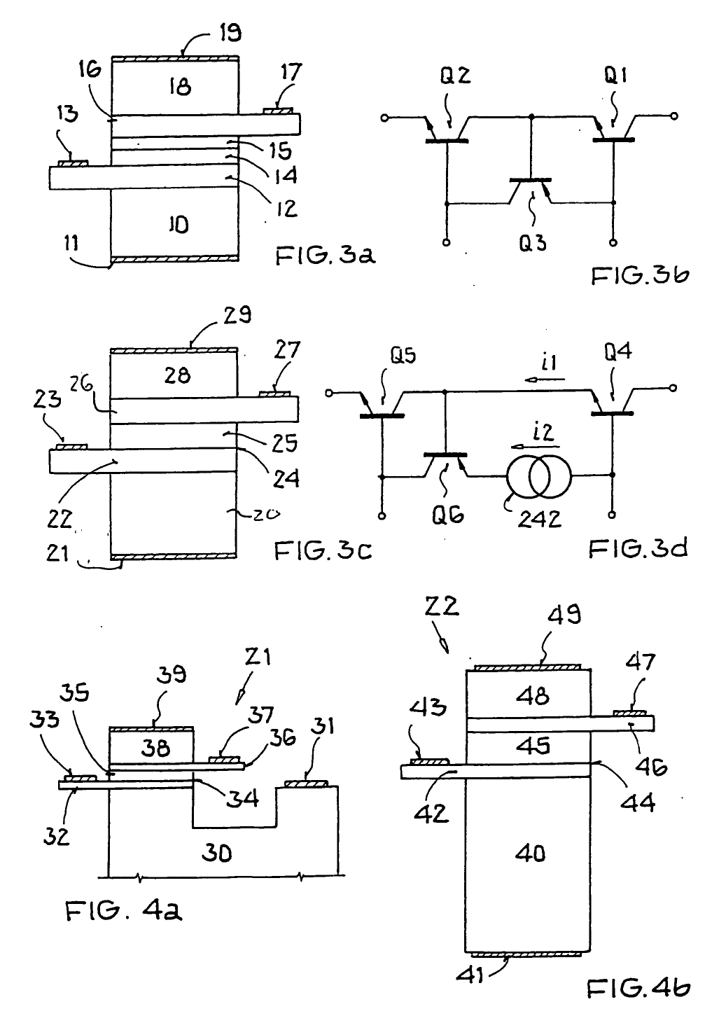

The invention will be explained below in connection with several schematized drawings. Here, the method according to claim 1 is shown in FIG. 1 and the suppression of the parasitic transistor in the method is explained with reference to FIGS. 2a and 2b. The method is compared with the conventional art with reference to FIGS. 3a to 3d. Finally, individual advantages of a high-frequency tetrode will be discussed with reference to FIG. 4a and individual advantages of a power tetrode with reference to FIG. 4b.

Active bipolar components are, inter alia, bipolar transistors of npn and pnp types, designated hereafter as transistors. Electrical characteristics for small-signal operation, such as the current gain β and Early voltage Vₐ, are important for the characterization of active components, such as, for example, transistors. Here, the current gain β is inversely proportional to the Gummel number G_{B}, the dopant integral over the uncleared base. By increasing the base-collector voltage, the uncleared base is reduced and the current gain β increased. A relative change in the current gain β is that much greater, the higher the current gain β, so that the product of the Early voltage Vₐ and the current gain β is limited.

The transient behavior and the blocking capability are important furthermore during use of active bipolar components as amplifier elements or switches. A characteristic for characterizing the transient behavior is the transition frequency f_{T}. The voltage swing ΔU_{c} achievable at the collector represents a characteristic for the blocking capability, which is inversely proportional to the collector doping level.

In high-blocking transistors, the transient behavior is determined primarily by the collector transit time. Here, the charge carriers traverse a blocked space-charge region at a saturation rate, so that the collector transit time at the maximum collector voltage is inversely proportional to the collector doping level. In the high-frequency range, the transient behavior is determined by the base transit time and the base charging time. The base-emitter capacitance is recharged during signal transmission. The recharging occurs the more rapidly, the higher the current density. By this means, the transition frequency f_{T} increases initially with an increasing collector current. If the density of the mobile charge carriers in the collector drift zone is comparable to the charging density of the ion cores, the effective base width increases (Kirk effect). As a result, the base transit time increases and the transition frequency f_{T} declines again at high current densities. Furthermore, the current density with a starting Kirk effect is proportional and the base charging time inversely proportional to the collector doping level. If the base transit and charging time are also disregarded, due to the transit time through the base-collector space-charge region, a material-dependent top limit results for the Johnson product, i.e., the product of the transition frequency f_{T} and voltage swing ΔU_{c}.

In hetero-bipolar transistors (HBT), the electrical properties, particularly the high-frequency properties, are improved by heterotransitions. A heterotransition is defined hereafter as a transition from a first semiconductor region of a first semiconductor material to a second semiconductor region of a second semiconductor material. Here, the transition can be made both abrupt, i.e., occur as an abrupt change between the first and the second semiconductor material, and also stepped or continuous by varying the composition in a transition region (mixed region) of the semiconductor material in steps or continuously.

A heterotransition of a hetero-bipolar transistor between base and collector makes it possible that the collector current of a transistor is proportional to the intrinsic charge carrier concentration in the base, whereas the intrinsic charge carrier concentration in the semiconductor increases exponentially with a declining value of the bandgaps. Hence, the collector current and consequently the current gain β are increased by reducing the bandgaps in the base of a transistor. At the same time, the blocking capability of a transistor depends inter alia on the breakdown field strength in the collector drift zone, which is approximately proportional to the square root of the third power of the value of the bandgap in the collector. Hence, a high blocking capability can be associated with a high current density, and with a high transition frequency f_{T}, which is above several GHz, due to a lower value for the bandgaps in the base than in the collector. A lower value for the bandgaps in the base than in the collector can be achieved in particular with the help of a heterotransition between the base and collector.

In a hetero-bipolar transistor (HBT) with a heterotransition between base and emitter, the edge of the band, which conducts the majority charge carriers in the emitter, lies in the base and emitter at comparable energies in the active forward operation. At different values for the bandgaps in the base and in the emitter, the edge of the band, which conducts the majority charge carriers in the base, lies in the base and emitter at different energies. If the value of the energy gap is selected as lower in the base in particular than in the emitter, then in the active forward operation of the transistor the movement of base majority charge carriers in the emitter is suppressed by an energy barrier, the base current is reduced, and the current gain β increased. A lower value of the bandgaps in the base than in the emitter can be achieved in particular with the help of a heterotransition between the base and emitter.

The base transit time can be reduced by a quasi-electric field, when in an uncleared semiconductor region with a position-independent electrochemical potential and a position-independent edge of the majority charge carrier band, a spatial change in the energy gap leads to a band edge slope in the minority charge carrier band. As a result, the minority charge carriers in the uncleared semiconductor region as well experience an accelerating field designated as quasi-electric, so that the base transit time is reduced and the transition frequency f_{T} increased.

In addition, the electrical properties of active semiconductor components can be improved by replacing an individual transistor in the emitter circuit with a resistive load at the collector with a—discretely constructed or laterally integrated—cascode circuit comprising a controlled transistor in the emitter circuit and an auxiliary transistor in the base circuit. Here, the auxiliary transistor supplies the resistive load. Due to the low input resistance of the auxiliary transistor, the controlled transistor experiences only a minor voltage swing ΔU_{c}, so that the cascode circuit at the same current gain β as that of the controlled transistor has a higher Early voltage Vₐ and the controlled transistor can be made low-blocking and rapid. A transistor is normally operated in the emitter circuit for the current gain. In contrast, the blocking capability in the base circuit is typically three times to ten times as high. Hence, by cascoding a transistor as an auxiliary transistor with a low-blocking controlled transistor, the achievable voltage swing ΔU_{c} and the Johnson product are increased. Furthermore, with the transition to the cascode circuit, the Miller effect is reduced and the transition frequency f_{T} increased. Frequencies in the range of several GHz can thus be achieved.

The achievable power amplification is important furthermore for the use of active components. Whereas the controlled transistor of a cascode circuit is used for current gain, the auxiliary transistor serves as an impedance converter for voltage amplification. The power amplification achieved with the cascode circuit is calculated as the product of power amplifications of the controlled transistor and the auxiliary transistor.

FIG. 1 shows the layer sequence of a conventional transistor T1. The transistor T1 has an n-doped collector layer 1, a p-doped base layer 2 adjacent to collector layer 1, and an n-doped emitter layer 3 adjacent to base layer 2.

Furthermore, FIG. 1 shows the layer sequence of a two-stage tetrode T2. The tetrode T2 is produced by the single application of the method from transistor T1 and comprises an n-doped collector layer 4, a p-doped first base layer 5 made of a first semiconductor material and adjacent to collector layer 4, a n-doped intermediate layer 6 made of a second semiconductor material and adjacent to first base layer 5, a p-doped second base layer 7 adjacent to intermediate base layer 6, and an n-doped emitter layer 8 adjacent to the second base layer 7. There is a heterotransition 9 between the first base layer 5 and the intermediate base layer 6. The first semiconductor material and the second semiconductor material meet the requirement that the value of the energy gap in the first semiconductor material is lower by at least the average thermal energy of the charge carriers than the value of the energy gap in the second semiconductor material.

A section line AA′ is drawn in the figure of the layer sequence of tetrode T2. The section line AA′ passes through part of intermediate base layer 6, through first base layer 5, and through part of collector layer 4. Along the section line AA′ the reference character 50 indicates the boundary between first base layer 5 and intermediate base layer 6 and the reference character 51 the boundary between collector layer 4 and first base layer 5.

Finally, FIG. 1 shows the layer sequence of a multistage tetrode T3. The tetrode T3 is produced by repeated use of the method on transistor T1 and comprises a collector layer C of the n-conductivity type and an emitter layer E of the n-conductivity type, between which there is an arrangement of r intermediate base layers of the n-conductivity type Z1, . . . , Zr and r+1, base layers B1, . . . , Bs of the p-conductivity type, each layer of the p-conductivity type being adjacent to precisely two layers of the n-conductivity type. There is a heterotransition H1, . . . , Hr between one first layer, adjacent to two layers of the p-conductivity type, and the downwardly adjacent second layer. In each case, a third material of the first layer and a fourth material of the second layer fulfill the condition that the value of the energy gap in the fourth material is lower by at least the average thermal energy of the charge carriers than in the third material.

The curves of individual characteristics along the sections through two embodiments of a two-stage tetrode with a collector of the n-conductivity type are shown in FIG. 2a and FIG. 2b. Here, the position coordinates are plotted horizontally along section line AA′ from the figure of the layer sequence of tetrode T2 of FIG. 1. The reference character Aa indicates the value of the position coordinate at point A. The reference character 50a marks the value of the position coordinate at the boundary 50 between first base layer 5 and intermediate base layer 6 along the section line AA′. The reference character 51a shows the value of the position coordinate at the boundary 51 between first base layer 5 and collector layer 4 along the section line AA′. The reference character Aa′ indicates the value of the position coordinate at point A′. The ordinate section 6a between Aa and 50a comprises position coordinates of points from intermediate base layer 6 and is designated as intermediate base section 6a. The ordinate section 5a between 50a and 51a comprises position coordinates of points from first base layer 5 and is designated as first base section 5a. The ordinate section 4a between 51a and Aa′ comprises position coordinates of points from collector layer 4 and is designated as collector section 4a.

The tetrode embodiments considered in FIG. 2a and FIG. 2b are made of mixed crystals SₓT₁₋ₓ of a first semiconductor material S and a second semiconductor material T. Here, the variable x gives the position-dependent mixture ratio. In the semiconductor material S, both the conduction band edge is considerably higher and the valence band edge considerably lower than in the semiconductor material T. Examples of such material pairs (S,T) lattice-matched to one another, which can easily be deposited epitaxially in any composition S₁₋ₓTₓ and for which suitable substrates are commercially available, comprise inter alia (Al_{0.48}In_{0.52}As,Ga_{0.47}In_{0.53}As), (Al_{0.52}In_{0.48}P,Ga_{0.52}In_{0.48}P), (Ga_{0.52}In_{0.48}P,GaAs), (InP,Ga_{0.47}In_{0.53}As), and (AlAs,GaAs).

Specifically, the mixture ratio x is plotted in FIG. 2a and the energy of the band edges versus the position coordinates along the section line AA′ in FIG. 2b.

A first curve 54 of the mixture ratio x for a first tetrode embodiment is shown in FIG. 2a as a solid line. In the first curve 54, the mixture ratio x in the intermediate base section 6a has the value 1; at the value 50a of the position coordinates, the value of the mixture ratio x jumps to a concentration parameter k. In the first base section 5a, the mixture ratio x declines, for example, linearly to zero and in collector section 4a it increases steadily to the value 1 in the interior of the collection section 4a. A tetrode, whose semiconductor material composition is described by the first curve 54 of the mixture ratio x, hence has, for example, intermediate base layer 6 between points A and 50 of the semiconductor material S, whereas at the heterotransition 9 the semiconductor material changes abruptly from the semiconductor material S on the side of intermediate base layer 6 to the semiconductor material SₖT₁₋ₖ on the side of the first base layer 5. A second curve 55 of the mixture ratio x for a second tetrode embodiment is shown by a dashed line where it deviates from the first curve 54. In the second curve 55, the value of the mixture ratio x at the value 51a of the position coordinate changes abruptly from zero to 1.

The band edge curves in the active forward operation of the first and the second tetrode embodiment are shown in FIG. 2b. Reference character 56 indicates the curve of the conduction band edge, shown by the solid line, and reference characteristic 58 the curve of the valence band edge, shown by the solid line, to the first curve 54 of the semiconductor material. In the intermediate base section 6a, the energy value of the conduction band edge 56 is position-independent. In the first base section 5a, the energy value of the conduction band edge 56 declines, for example, linearly with a gradient, which is proportional to the concentration parameter k. At the value 51a of the position coordinate, the curve of the conduction band edge 56 is continuous, to decline initially in the collector section 4a and finally to change to a position-independent curve. The curve of the valence band edge 58 deviates from the curve of the conduction band edge 56 primarily in an upward jump from intermediate base layer 6a to first base section 5a. The abrupt curve of the valence band edge 58 at the value 50a of the position coordinate is produced by the heterotransition 9 between intermediate base layer 6 and first base layer 5 of the tetrode. The dashed line shows the curve of the conduction band edge 57 where it deviates from the curve of the conduction band edge 56 and the curve of the valence band edge 59 to the second curve 55 of the semiconductor material where it deviates from the curve of the valence band edge 58. The curve of the conduction band edge 57 shows, deviating from the curve of the conduction band edge 56, a step upward from the first base section 5a to the collector section 4a, to join the curve of the conduction band edge 56 within collection section 4a. The curve of valence band edge 59 shows, deviating from the curve of valence band edge 58, a step down from first base section 5a to collector section 4a, to join the curve of valence band edge 58 within collection section 4a.

A collector current of the tetrode in FIG. 2b corresponds primarily to electron movement from left to right, whereas a hole drift is directed from right to left. The gradient in conduction band edges 56, 57, which is proportional to the value of the concentration parameter k, causes a quasi-electric field accelerating the electrons in collector section 4a in the first base section 5a. This increases the transition frequency f_{T} of the considered tetrode embodiments.

The electrons above the conduction band edges 56, 57 can move largely unimpeded from intermediate base section 6a to first base section 5a. The holes are located in a narrow energy region below valence band edges 58, 59, so that at the value 50a of the position coordinates, the movement of holes from first base section 5a to intermediate base section 6a is made difficult by the abrupt curve of valence band edges 58, 59. This is the basis for the suppression according to the invention of the parasitic transistor with the use of heterotransition 9 of the tetrode. In the second curve 55 of the mixture ratio x for the second tetrode embodiment, furthermore, at the value 51a of the position coordinate the electron movement from first base section 5a to collector section 4a is impeded by the jump in conduction band edge 57 and the collector current is reduced. As a result, at the relative band positions in the semiconductor materials S and T, the first curve 54 appears advantageous compared with the second curve 55.

A schematized cross section through a vertically integrated cascode structure, known from D2, is shown in FIG. 3a. The vertically integrated cascode structure comprises first an n-doped collector region 10 with a back collector contact 11, a p-doped first base region 12, which lies on collector region 10, with a first base contact 13, and an n-doped intermediate base region lying on first base region 12. The intermediate base region consists of a first subregion 14, adjacent to first base region 12, with a high dopant concentration and of a second subregion 15 with a low dopant concentration. The vertically integrated cascode structure comprises furthermore a p-doped second base region 16, lying partially on subregion 15, with a second base contact 17, as well as an n-doped emitter region 18, lying on second base region 16, with an emitter contact 19. The vertically integrated cascode structure from D2 contains a collector-side and an emitter-side npn transistor and has a parasitic pnp transistor. The collector-side npn transistor is formed by collector region 10, first base region 12, and first subregion 14 of the intermediate base region; the emitter-side npn transistor consists of second subregion 15 of the intermediate base region, second base region 16, and emitter region 18, whereas the parasitic pnp transistor comprises first base region 12, the two subregions 14, 15 of the intermediate base region, and second base region 16.

If the first subregion 14 of the intermediate base region is used electrically as the emitter of the collector-side npn transistor and the second subregion 15 of the intermediate base region as the collector of the emitter-side npn transistor, the equivalent circuit shown in FIG. 3b results. The collector-side npn transistor is depicted by a transistor Q1, the emitter-side npn transistor by a transistor Q2, and the parasitic pnp transistor by a transistor Q3. The collector of transistor Q2 is connected to the base of transistor Q3 and the emitter of transistor Q1, the emitter of transistor Q3 to the base of transistor Q1, and the collector of transistor Q3 to the base of transistor Q2.

Hence, a circuit element, which consists of transistors Q1 and Q2, of the equivalent circuit of the vertically integrated cascode structure from D2 is the equivalent circuit of a thyristor. In order to be able to operate the cascode structure as a cascode, the product β₁·β₃ of the current gains β₁ of transistor Q1 and β₃ of transistor Q3 must be made small, preferably less than one. Voltage changes at the base of transistor Q1 are transmitted directly to the emitter of transistor Q2. In order to achieve a high output resistance with the cascode structure during operation of transistor Q1 in the basic circuit, hence, a low-resistance voltage source is necessary to supply the base of transistor Q1 primarily at a low current gain β₁ of transistor Q1.

A principle of the arrangement disclosed in D2 is to reduce the product β₁·β₃ of the current gains of transistors Q1 and Q3 by increasing the dopant integral over subregions 14, 15 of the intermediate base region. It is a disadvantage that as a result the Johnson product is reduced in the high-frequency range.

A schematized cross section through an embodiment of a contacted two-stage tetrode is shown in FIG. 3c; it is made of an n-doped collector region 20 with a back collector contact 21, a p-doped first base region 22, lying on collector region 20, of a fifth semiconductor material with a first base contact 23, an n-doped intermediate base region 25, lying on first base region 22, of a sixth semiconductor material, a p-doped second base region 26, lying partially on intermediate base region 25, with a second base contact 27, and an n-doped emitter region 28, lying on second base region 26, with an emitter contact 29. There is a heterotransition 24 between first base region 22 and intermediate base region 25. The value of the energy gap is considerably lower in the fifth semiconductor material than in the sixth semiconductor material. The valence band edge is considerably higher in the fifth semiconductor material than in the sixth semiconductor material.

The tetrode shown in FIG. 3c in the schematized cross section is a vertically integrated cascode structure comprising a collector-side and an emitter-side npn transistor and has a parasitic pnp transistor. The collector-side npn transistor is formed by collector region 20, first base region 22, and intermediate base region 25; the emitter-side npn transistor consists of intermediate base region 25, second base region 26, and emitter region 28, whereas the parasitic pnp transistor comprises first base region 22, the intermediate base region 25, and second base region 26.

Intermediate base region 25 is interpreted hereafter as the emitter of the collector-side and as the collector of the emitter-side npn transistor and the first base region 22 as the emitter of the parasitic pnp transistor. The pn transition between first base region 22 and intermediate base region 25 hence serves both as an emitter diode of the collector-side npn transistor and also as the emitter diode of the parasitic pnp transistor. Electrons, flowing from intermediate base region 25 to first base region 22, can carry the emitter current of the collector-side npn transistor, but holes, flowing from first base region 22 to intermediate base region 25, the emitter current of the parasitic pnp transistor. Whereas a flow of electrons from intermediate base region 25 to first base region 22 is not limited by heterotransition 24, an opposite flow of holes is suppressed due to the different energy positions of the valence band edges in the fifth and sixth semiconductor material.

The equivalent circuit shown in FIG. 3d results. The collector-side npn transistor is depicted by a transistor Q4, the emitter-side npn transistor by a transistor Q5, and the parasitic pnp transistor by a transistor Q6. The collector of transistor Q5 is connected to the base of transistor Q6 and the emitter of transistor Q4, the emitter of transistor Q6 to the base of transistor Q4 via a regulated current source 242, and the collector of transistor Q6 to the base of transistor Q5. The current across the pn transition between first base region 22 and intermediate base region 25 can be divided into a current i1 carried by electrons and a current i2 carried by holes. The current i1 is the emitter current of transistor Q4 and current i2 the emitter current of transistor Q6. The magnitude of the current i2 is controlled by the regulated current source 242, which hence describes the effect of heterotransition 24 on the flow of holes from first base region 22 to intermediate base region 25.

An advantage of the exemplary embodiment of FIG. 3c, and/or FIG. 3d, versus the cascode arrangement from D1 is that the collector current and thereby the output signal remain controllable by an input signal within a greater range of operating states.

An advantage of the exemplary embodiment of FIG. 3c, and/or FIG. 3d, versus the cascode arrangement of D2 is that no high Gummel number G_{B} of the parasitic transistor is necessary for suppression of thyristor-like behavior, so that particularly low-blocking, high-frequency-capable components with considerably increased values for the transition frequency f_{T} and of the Johnson product can be produced.

Compared with individual transistors, the achievable values in particular for the transition frequency f_{T}, for the Johnson-product, for the power amplification, and for the product of Early voltage Vₐ and current gain β in this exemplary embodiment are increased. Moreover, in comparison with cascode circuits made from discrete elements or laterally integrated, the signal transit time between the bases of the cascoded transistors is reduced and thereby the achievable value for the transition frequency f_{T} and for the Johnson product increased. Furthermore, the chip area requirement, which is increased with a transition from a transistor to a laterally integrated cascode circuit, is avoided, and, moreover, the required number of components compared with individual components is reduced.

An advantage of the exemplary embodiments shown in FIGS. 3c, 3d, 4a, and 4b is the suppression of the parasitic transistor of a vertically integrated cascode structure by reducing the magnitude of current i2 to a magnitude negligible in comparison with the magnitude of current i1 by a heterotransition, for example, the heterotransition 24 of the tetrode shown in FIG. 3c. Unlike the arrangement shown in FIG. 3a from D2, in the tetrode the tendency for thyristor-like behavior is accordingly reduced by controlling the magnitude of the emitter current i2 of parasitic transistor Q6 and without a high Gummel number GB of the semiconductor region between the bases of the vertically integrated transistor.

Two examples of tetrodes will be shown below in FIGS. 4a and 4b. In a schematized cross section, FIG. 4a shows an embodiment of a two-stage tetrode with excellent high-frequency behavior and FIG. 4b an embodiment of a two-stage tetrode, which is especially suitable for high blocking voltages. The numerical data represent approximate values here.

A schematized cross section through a contacted, two-stage tetrode Z1 suitable for the highest frequencies is shown in FIG. 4a. The tetrode Z1 comprises a 300 nm-thick collector region 30 of silicon, doped with 1.5e17 cm⁻³ of arsenic and contacted from the front of the semiconductor body, with a collector contact 31, a 17 nm-thick first base region 32 of Si_{0.75}Ge_{0.25} and doped with 3e19 cm⁻³ of boron with a first base contact 33, a 50 nm-thick silicon intermediate base region 35, doped with 1e18 cm⁻³ of arsenic, a 17 nm-thick second base region 36 of Si_{0.75}Ge_{0.25}, doped with 3e19 cm⁻³ of boron, with a second base contact 37, and a 50 nm-thick emitter region 38 of silicon, doped with 2e18 cm⁻³ of arsenic, with an emitter contact 39. A collector-side npn transistor is formed by collector region 30 as collector, first base region 32 as base, and intermediate base region 35 as emitter, whereas an emitter-side npn transistor is formed of intermediate base region 35 as collector, second base region 36 as base, and emitter region 38 as emitter, and a parasitic pnp transistor comprises first base region 32 as emitter, intermediate base region 35 as base, and second base region 36 as collector. In the collector-side npn transistor, the base-collector breakdown voltage is 9.5 V and the emitter-collector-breakdown voltage 2.5 V, whereas the emitter-side npn transistor has an emitter-collector breakdown voltage of 1.1 V. There is a heterotransition 34 between first base region 32 and intermediate base region 35, the heterotransition by which the flow of holes from first base region 32 to intermediate base region 35 is suppressed. The diode of intermediate base region 35 and second base region 36 of tetrode Z1 has a breakdown due to interband tunneling and is designated hereafter as the “Zener diode.”

Individual advantages of the tetrode Z1 will be explained below and for that purpose an operating point will be described at which the tetrode Z1 is operated. The potential at emitter contact 39 of tetrode Z1 serves as voltage reference here, whereas at first base contact 33 a voltage of 2 V is applied and collector contact 31 is connected by a suitable resistor to a supply voltage of 9 V. The collector current of tetrode Z1 is controlled by impressing a control current on second base contact 37, the voltage at second base contact 37 being adjusted to a control current-dependent value U1.

The major portion of the currents through the tetrode Z1 is carried by electrons, which flow from emitter region 38 through second base region 36, through intermediate base region 35, and through first base region 34 into collector region 34. Herewith, the collector currents in the emitter-side and in the collector-side npn transistor and thereby the base-emitter voltages are the same. With a voltage at second base contact 37 with the value U₁, accordingly a voltage of 2 V-2 U₁ arises via the diode from the uncontacted intermediate base region 35 and second base contact 37.

A comparison transistor A1, manufactured like tetrode Z1 using a comparable technology generation, serves furthermore to demonstrate the individual advantages of tetrode Z1. The comparison transistor A1 is obtained from tetrode Z1 by eliminating second base region 36 including second base contact 37 and intermediate base region 35, so that in the comparison transistor A1 the emitter region is adjacent to first base region 32 of tetrode Z1.

During operation of tetrode Z1, the collector of the emitter-side npn transistor is shielded against voltage variations in collector region 30 by the collector-side npn transistor. At the same current gain β, by this means, a considerably higher Early voltage Vₐ is achieved with tetrode Z1 than with the comparison transistor A1. Furthermore, the blocking capability of tetrode Z1 is determined by the breakdown voltage between first base region 32 and collector region 30, so that at a comparable doping level in collector region 30, a considerably higher blocking capability is achieved with tetrode Z1 than with the comparison transistor A1 in the emitter circuit.

The tetrode Z1 is a special vertically integrated cascode structure. At the selected operating point, the behavior of tetrode Z1 deviates from that of a known cascode circuit, however. A reason for this is that the emitter-collector breakdown voltage in the emitter-side npn transistor of tetrode Z1 is lower than the voltage between emitter region 38 and first base region 32.

At voltages U1, above about 0.9 V, or blocking voltages across the Zener diode below about 0.2 V, the behavior of tetrode Z1 is not substantially influenced by interband tunneling in the Zener diode. The blocking voltage across the Zener diode and the rate of interband tunneling are increased by a declining control current. The holes produced hereby are available as additional current in second base region 36 and contribute, multiplied with the current gain β of the emitter-side npn transistor, to the collector current. The base-emitter voltage is increased by the increasing collector current, and the voltage across the Zener diode and the interband tunneling rate are reduced again. An oscillation tendency exhibited by the individual tetrode embodiments is enhanced by operation of the tetrode Z1 at an operating point at which the potential in intermediate base region 35 exceeds the emitter-collector breakdown voltage of the emitter-side npn transistor. Particularly, here, tetrode Z1 becomes an oscillator and can be used, for example, in conjunction with a resonator, advantageously as an oscillation source, or in conjunction with a high-pass, as an amplifying component for the highest frequencies.

At a voltage of 2 V at the first base contact 33 and a base collector breakdown voltage in the collector-side npn transistor of 9.5 V, the voltage in the collector region 30 can be between about 2 V and about 9 V, so that a voltage swing ΔU_{c} of about 7 V is achieved with tetrode Z1. At a transition frequency of 200 GHz, a Johnson product of 1400 GHz·V is achieved accordingly. The comparison transistor A1 by comparison at a transition frequency of 105 GHz at a dielectric strength in the emitter circuit of 2 V has a Johnson product of only 310 GHz·V. By replacing transistor A1 with tetrode Z1, hence the Johnson product is greatly increased, whereas the manufacturing costs rise only slightly.

At potentials at first base contact 33 above the emitter-collector breakdown voltage of the emitter-side npn transistor of tetrode Z1, the collector current cannot be turned off by the control current as a result of interband tunneling, but must be interrupted by circuitry means suitable for this.

By reducing the dopant concentration in intermediate base region 35 of tetrode Z1, the interband tunneling rate in the Zener diode is reduced and the stable tetrode operating range increased. At the same time, in order to avoid a punch-through between first base region 32 and second base region 36, intermediate base region 35 must be made thicker. The transition frequency f_{T} is reduced as a result. As an example, a transition frequency f_{T} of 160 GHz is achieved at a voltage swing ΔU_{c} of about 7 V with a tetrode, which differs from tetrode Z1 in a 250 nm-thick intermediate base region made of silicon and doped with 1.5e17 cm⁻³ of arsenic.

A schematized cross section through a highly voltage-proof, contacted, two-stage tetrode Z2 is shown in FIG. 4b. Tetrode Z2 comprises a 50 μm-thick silicon collector region 40, doped with 4e14 cm⁻³ of arsenic, and contacted from the back of the semiconductor body, with a collector contact 41, a 17 nm-thick first base region 42 of Si_{0.75}Ge_{0.25}, doped with 3e19 cm⁻³ of boron, with a first base contact 43, a 350 nm-thick silicon intermediate base region 45, doped with 3e19 cm⁻³ of arsenic, a 17 nm-thick second base region 46 of Si_{0.75}Ge_{0.25}, doped with 3e19 cm⁻³ of boron, with a second base contact 47, and a 50 nm-thick silicon emitter region 48, doped with 2e18 cm⁻³ of arsenic, with an emitter contact 49. A collector-side npn transistor is formed by collector region 40 as collector, first base region 42 as base, and intermediate base region 45 as emitter, whereas an emitter-side npn transistor consists of intermediate base region 45 as collector, second base region 46 as base, and emitter region 48 as emitter, and a parasitic pnp transistor comprises first base region 42 as emitter, intermediate base region 45 as base, and second base region 46 as collector. The base-collector breakdown voltage of the collector-side npn transistor is 500 V and the emitter-collector breakdown voltage 200 V, whereas the emitter-side npn transistor has an emitter-collector breakdown voltage of 4 V. There is a heterotransition 44 between first base region 42 and intermediate base region 45. Holes in the transition from first base region 42 to intermediate base region 45 are impeded by heterotransition 44.

The individual advantages of tetrode Z2 are explained below. The potential at emitter contact 49 serves hereby as the voltage reference. The collector current is controlled by impression of a control current on the second base contact 47.2 V are applied at the first base contact 43, and collector contact 31 is connected through a resistor to a voltage of 500 V.

A comparison transistor A2, manufactured like tetrode Z2 using a comparable technology generation, serves furthermore to demonstrate the individual advantages of tetrode Z1. The comparison transistor A2 is obtained from tetrode Z2 by eliminating the second base region 46 including the second base contact 47, as well as intermediate base region 45, so that in the comparison transistor A2 the emitter region is adjacent to first base region 42 of tetrode Z2.

During operation of tetrode Z2, the collector of the emitter-side npn transistor is shielded against voltage variations in the collector region 30 by the collector-side npn transistor. At the same current gain β, by this means, a considerably higher Early voltage Vₐ is achieved with tetrode Z2 than with the comparison transistor A2. Furthermore, the blocking capability of tetrode Z2 is determined by the breakdown voltage between first base region 42 and collector region 40, so that at a comparable doping level in collector region 40, a considerably higher blocking capability is achieved with tetrode Z2 than with the comparison transistor A2 in emitter circuit.

A voltage swing ΔU_{c} of 500 V and a Johnson product of 200 GHz·V are achieved with tetrode Z2 at a transition frequency of 330 MHz. The comparison transistor A2, on the contrary, at a transition frequency of 570 MHz at a dielectric strength in the emitter circuit of 200 V has a Johnson product of only 115 GHz·V typical for high-blocking transistors. Hence, the Johnson product is increased by replacing transistor A2 with tetrode Z2.

At an active component used as a binary switch, the losses in the “on” and “off” state are considerably lower than the losses during the switching. An increase in the switching speed by reducing the effective capacitance lowers the energy deposited in the active component per switching operation and heating of the component. In modern power components, the clock speed is limited by the power that can be removed, for example, via the housing. Hence, the higher the transition frequency f_{T} of an active component, the higher in general the achievable clock speed. The achievable clock speed can be doubled by replacing a high-blocking power transistor having a Johnson product of, for example, 100 GHz with a power tetrode having the same blocking capability but a Johnson product of, for example, 200 GHz.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A method for providing a bipolar transistor, the method comprising the steps of:
providing a first semiconductor region of a first conductivity type;
providing a second semiconductor region adjacent to the first semiconductor region; and
providing a third semiconductor region of the first conductivity type that is adjacent to the second semiconductor region;
wherein the second semiconductor region is formed of:
a fourth semiconductor region of a second conductivity type and made of a first semiconductor material is provided so that the fourth semiconductor region is adjacent to the first semiconductor region, the second conductivity type being different than the first conductivity type;
a fifth semiconductor region made of the first conductivity type of a second semiconductor material is provided so that the fifth semiconductor region is adjacent to the fourth semiconductor region; and
a sixth semiconductor region of the second conductivity type is provided so that the sixth semiconductor region is adjacent to the fifth semiconductor region and the third semiconductor region,
wherein a value of an energy gap in the first semiconductor material is lower by at least an average thermal energy of charge carriers than a value of the energy gap in the second semiconductor material, and
wherein the fifth semiconductor region is homogeneously doped.

2. The method according to claim 1, wherein the third semiconductor region is made from a third semiconductor material and the sixth semiconductor region is made from a fourth semiconductor material, wherein a value of the energy gap in the fourth semiconductor material is lower by at least the average thermal energy of the charge carriers than a value of the energy gap in the third semiconductor material.

3. The method according to claim 1, wherein a wider bandgap is produced in the fourth semiconductor region at an edge to the fifth semiconductor region than at an edge to the first semiconductor region.

4. The method according to claim 1, wherein a wider bandgap is produced in the sixth semiconductor region at an edge to the third semiconductor region than at an edge to the fifth semiconductor region.

5. The method according to claim 1, wherein the fourth semiconductor region is made from a different semiconductor material than the first semiconductor region.

6. The method according to claim 1, wherein the sixth semiconductor region is made from a different semiconductor material than the fifth semiconductor region.

7. The method according to claim 1, wherein the fifth semiconductor region is made with a higher dopant concentration than the first semiconductor region.

8. The method according to claim 1, wherein the fifth semiconductor region is made with a substantially similiar dopant concentration as the first semiconductor region.

9. The method according to claim 1, wherein the fifth semiconductor region is made from n-doped Si and the fourth semiconductor region is made from p-doped SiGe.

10. A multilayer component, comprising
a first number of semiconductor layers of a first conductivity type; and
a second number of semiconductor layers of a second conductivity type,
wherein the first number is greater than the number one and the second number is greater by one than the first number,
wherein each semiconductor layer of the first conductivity type is adjacent to two of the semiconductor layers of the second conductivity type,
wherein a first semiconductor layer of the second number, adjacent to two semiconductor layers of the first number is made of a first semiconductor material,
wherein a second semiconductor layer of the first number, adjacent to the first semiconductor layer is made of a second semiconductor material,
wherein the first semiconductor layer has a homogeneous dopant distribution, and
wherein a value of an energy gap in the second semiconductor material is lower by at least an average thermal energy of charge carriers than a value of an energy gap in the first semiconductor material.

11. The multilayer component according to claim 10, wherein at least one semiconductor layer of the second conductivity type, adjacent to two semiconductor layers of the first conductivity type, has an electrical contact.

12. The multilayer component according to claim 10, wherein all semiconductor layers contacted in a semiconductor body are contacted to a front of the semiconductor body.

13. The multilayer component according to claim 10, wherein a semiconductor layer facing a back of the semiconductor body is contacted from the back.

14. The multilayer component according to claim 10, wherein the multilayer component is a high-blocking active component, in a voltage range in which the transient behavior is determined essentially by a transit time through a space-charge region between a first semiconductor region and a fourth semiconductor region.

15. The multilayer component according to claim 10, wherein the multilayer component is a highest-frequency-capable active component, within a frequency range in which a transient behavior is substantially influenced by the Miller effect.

16. A high-frequency cascode circuit comprising:
a first transistor, which is operated in a base circuit; and
a second transistor, which is operated in an emitter circuit;
wherein the emitter of the second transistor and the collector of the first transistor form a continuous intermediate base region,
wherein a base-intermediate base transition of the first transistor is a heterotransition, and
wherein the intermediate base region is homogeneously doped.

17. The high-frequency cascode circuit according to claim 16, wherein the intermediate base region has a dopant concentration of at least 1·10¹⁷ cm⁻³ or greater than 5·10¹⁷ cm^{-3.}

18. The high-frequency cascode circuit according to claim 16, wherein the intermediate base region has a thickness of less than 200 nm or less than 100 nm.

19. A method for manufacturing a multilayer component, the method comprising the steps of:
providing a first number of semiconductor layers of a first conductivity type; and
providing second number of semiconductor layers of a second conductivity type,
wherein the first number is greater than the number one and the second number is greater by one than the first number,
wherein each semiconductor layer of the first conductivity type is adjacent to two of the semiconductor layers of the second conductivity type,
wherein a first semiconductor layer of the second conductivity type, adjacent to two semiconductor layers of the first conductivity type, is formed from a first semiconductor material,
wherein a second semiconductor layer, adjacent to the first semiconductor layer, is formed from a second semiconductor material, whose value for an energy gap is lower by at least an average thermal energy of charge carriers than a value of an energy gap in the first semiconductor material, and
wherein a dopant is homogeneously distributed in the first semiconductor layer.
